(19) United States
(12) Patent Application Publication
(10) Pub. No.: US 2015/0244329 A1
(43) Pub. Date: Aug. 27, 2015

(54) Technique for Extremely High Order IM Correction

(71) Applicants: NOKIA SIEMENS NETWORKS OY, Espoo (FI); NOKIA SIEMENS NETWORKS US LLC, Irving, TX (US)

(72) Inventors: Shavantha Kularatna, Flower Mound, TX (US); Bjoern Jelonnek, Ulm (DE); Kevin Bastin, San Diego, CA (US); Chia Sam Wey, Colleyville, TX (US)

(73) Assignee: Nokia Solutions and Networks Oy, Espoo (FI)

(21) Appl. No.: 14/436,275

(22) PCT Filed: Oct. 16, 2012
(86) PCT No.: PCT/US12/60390

§ 371 Date: Apr. 16, 2015

(51) Int. Cl. H03F 1/32; H03F 3/21; H03F 3/19; H04B 1/04

(52) U.S. Cl. CPC H03F 1/3241; H04B 1/0475; H03F 3/21; H03F 3/19; H04B 2001/0425; H03F 2200/451; H03F 2201/3215

(57) ABSTRACT

A method for correcting high order IM products is described. The method includes creating a modified input signal by increasing one or more portions of an input signal (such as the whole time domain signal for example). The input signal consists of a desired signal and other non-linear products. Each of the one or more portions includes high order IM products. A pre-distorted signal is created by pre-distorting the modified input signal in accordance with a finite signal plan. An output signal is generated by amplifying the pre-distorted signal. Apparatus and computer-readable media are also described.

### TECHNICAL FIELD

The exemplary and non-limiting embodiments relate generally to wireless communication systems, methods, devices and computer programs and, more specifically, relate to high order intermodulation correction.

### BACKGROUND

This section is intended to provide a background or context. The description herein may include concepts that could be pursued, but are not necessarily ones that have been previously conceived or pursued. Therefore, unless otherwise indicated herein, what is described in this section is not prior art to the description and claims in this application and is not admitted to be prior art by inclusion in this section.

Many radios (such as those in base stations or a mobile device for example) have power amplifier (PA) devices to boost a low power signal into a high power signal for transmission. In one non-limiting example, a power amplifier includes a linear driver stage followed by a high gain final stage device. The linear driver stage receives an input signal and prepares the signal for amplification by the final stage device. The linear drive adjusts the input signal in order to compensate for non-linear characteristics for the final stage device.

### SUMMARY

The below summary section is intended to be merely exemplary and non-limiting.

The foregoing and other problems are overcome, and other advantages are realized, by the use of the exemplary embodiments.

In a first aspect thereof an exemplary embodiment provides a method for correcting high order IM products. The method includes creating a modified input signal by increasing one or more portions of an input signal. The input signal consists of a desired signal and other non-linear products. Each of the one or more portions includes high order IM products (such as 11^{th} order products and above for example). A pre-distorted signal is created by pre-distorting the modified input signal in accordance with a finite signal plan. An output signal is generated by amplifying the pre-distorted signal.

Another exemplary embodiment provides an apparatus for correcting high order IM products. The apparatus includes at least one processor; and at least one memory storing computer program code. The at least one memory and the computer program code are configured to, with the at least one processor, cause the apparatus to perform actions. The actions include to create a modified input signal by increasing one or more portions of an input signal. The input signal consists of a desired signal and other non-linear products. Each of the one or more portions includes high order IM products. A pre-distorted signal is created by pre-distorting the modified input signal in accordance with a finite signal plan. The actions also include to create an output signal by amplifying the pre-distorted signal.

A further exemplary embodiment provides a computer readable medium for correcting high order IM products. The computer readable medium is tangibly encoded with a computer program executable by a processor to perform actions. The actions include creating a modified input signal by increasing one or more portions of an input signal. The input signal consists of a desired signal and other non-linear products. Each of the one or more portions includes high order IM products. A pre-distorted signal is created by pre-distorting the modified input signal in accordance with a finite signal plan. The actions also include creating an output signal by amplifying the pre-distorted signal.

Another exemplary embodiment provides an apparatus for correcting high order IM products. The apparatus includes means for creating a modified input signal by increasing one or more portions of an input signal. The input signal consists of a desired signal and other non-linear products. Each of the one or more portions includes high order IM products. The apparatus includes means for creating a pre-distorted signal by pre-distorting the modified input signal in accordance with a finite signal plan. The apparatus also includes means for creating an output signal by amplifying the pre-distorted signal.

### BRIEF DESCRIPTION OF THE DRAWINGS

The foregoing and other aspects of exemplary embodiments are made more evident in the following Detailed Description, when read in conjunction with the attached Drawing Figures, wherein:

FIG. 1 illustrates intermodulation products of two high power rated power amplifiers.

FIG. 2A illustrates two signals, each having high order intermodulation products.

FIG. 2B is a zoomed-in portion of FIG. 2A.

FIG. 3 shows a simplified block diagram of exemplary electronic devices that are suitable for use in practicing various exemplary embodiments.

FIG. 4 shows a more particularized block diagram of a power amplifier circuit such as that shown at FIG. 3.

FIG. 5 is a logic flow diagram that illustrates the operation of an exemplary method, and a result of execution of computer program instructions embodied on a computer readable memory, in accordance with various exemplary embodiments.

### DETAILED DESCRIPTION

Due to conflicting pressures of cost and available power, the final stage of a PA device may be driven hard in compression regions. Such compression may cause non-linearities (or non-linear products) in the output signal. These non-linear products are also referred to as intermodulation (IM) distortion products. The IM products may cause adjacent channel interference, which in turn causes degradation of the signal quality in adjacent cells. Thus, a network level throughput reduction may result when the power amplifier creates such non-linear output.

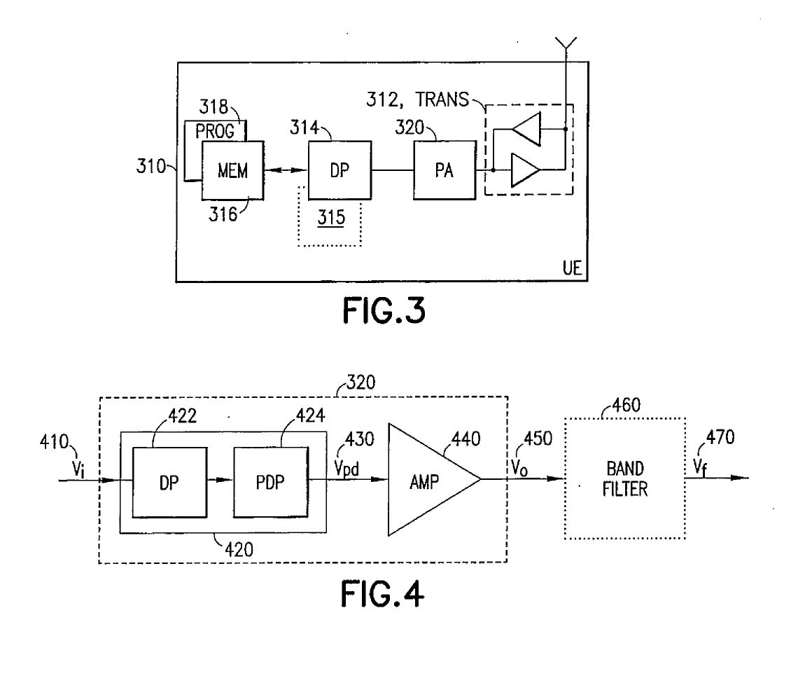

FIG. 4 shows a block diagram of a non-limiting embodiment of a power amplifier (PA) 320. The PA 320 receives an input signal 410, Vᵢ. The input signal 410 is received at a linear driver stage 420 of the PA 320. A DP 422 modifies the input signal 410, Vᵢ, such as by increasing various portions of the input signal 410. These portions correspond to parts of the input signal which include high order IM products, such as those of 13^{th} order and above for example. The modified signal is then pre-distorted by pre-distortion processor (PDP) 424 to create a pre-distorted signal 430, V_{pd}. The pre-distorted signal 430 is then provided to a high gain final stage 440 which boosts the signal to the target level.

The output signal 450, Vₒ, from the high gain final stage 440 may then be provided to the RF transceiver 312. Alternatively, the output signal 450 may be passed through a band filter 460 generating a filtered output signal 470, V_{f}, for transmission.

Various exemplary embodiments solve the IM product problem with a technique whereby the input signal level plan is increased compared to the common level plan (such as by 1 dB, 2 dB, 3 dB, or 3.3 dB as non-limiting examples) in regions that include high order IM products. The increase in level corresponds to the whole time domain signal including the desired signal and any non-linear products.

In a further non-limiting example, the increase in the level may be applied for digital pre-distortion. Upon processing, the signal is lowered before being sent to the analog part (such as the PA 320 for example). Thus, the input signal 410 level may be increased. However, then before supplying the pre-distorted signal 430 to the PA, the raised level is reduced (after DPD processing) which makes it neutral for the whole system.

Digital pre-distortion (DPD) may be used to suppress various unwanted IM products. In certain applications, extremely high order products may be located out of the frequency band being used and, as such, experience further suppression from a band filter (such as a cavity filter for example). Thus, a DPD system that corrects IM products only up to the 13^{th} order may be deemed sufficient for such applications. Many waveforms (such as those for GSM, LTE, WCDMA and multi-carrier combinations of the above for example) can benefit from DPD correction. Lower order products that are seen in the radio band used can be corrected easily and higher orders products are out of the band and experience further attenuation from the band filter.

However, there are instances where such low-order DPD systems fail, such as by causing 3GPP non-compliant results for example. An example of such a situation is when the DPD is used to attempt to correct extremely high order IM products. An extremely high order may be one that is greater than (or equal to) the 13^{th} order (such as 15^{th}, 17th, 19^{th}, 21^{st}, etc. for example). When using a large radio band, such as an 1800 MHz allocation (transmitting between 1805 MHz to 1880 MHz) for example, the high order products should not be neglected.

When high order IM products aren't corrected by the DPD algorithm, these products may fall within the radio band. Hence the band filter will not suppress them. This is a problem that is common to all pre-distortion algorithms. Accordingly, many conventional wireless devices experience this problem. In one non-limiting example, a mobile device may use a GSM 2 carrier signal which has a separation of 0.6 MHz and 1 MHz and may experience high order IM products that are within the 1800 MHz band.

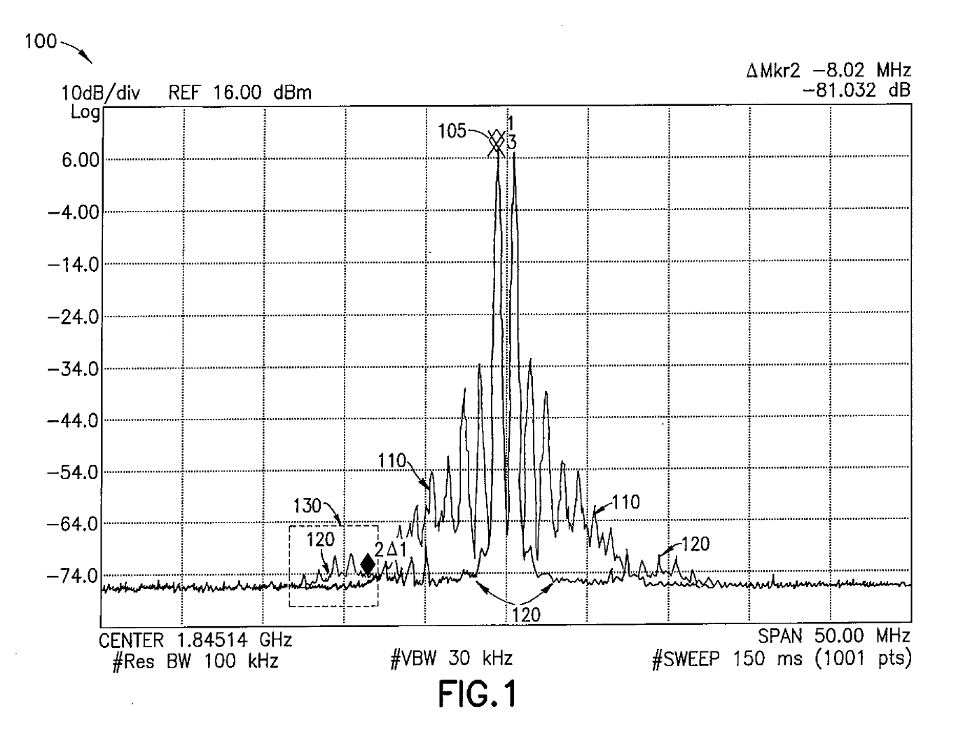

FIG. 1 is a graph 100 which illustrates two signals, each having high order intermodulation products. The signals include a 17th order intermodulation product at point 105 as well as other IM products (such as the 19th and 21st order for example). Line 110 shows the result of a high power rated power amplifier using an input signal having an uncorrected 17th order product and line 120 shows the result of a high power rated power amplifier using an input signal having a pre-distortion 17th order product. Area 130 highlights a portion of the graph where the pre-distortion product amplifier (line 120) produces more noise than the uncorrected 17th order product amplifier (line 110).

Point 105 corresponds to a part of the signals which include the 17th order intermodulation product. Line 110 shows results where linearization is not applied and line 120 shows results where linearization alone is applied. Accordingly, applying linearization alone may have caused much more harm than when linearization is not applied.

As shown in FIG. 1, the uncorrected 17th order product (line 110) may fall below a noise floor (such as suppression in excess of 82 dBc for example). Using DPD, the 17th order IM product degrades to −79 dBc (line 120). Thus, even though a product in accordance with line 120 may pass a 3GPP wideband noise specification, the DPD algorithm used fails for area 130. In other words, it is better not to apply DPD at such high order products as performance would have been better without having the DPD applied.

Based on the foregoing it should be apparent that various exemplary embodiments provide a method, apparatus and computer program(s) to correct high order intermodulation products such as that seen in FIG. 1.

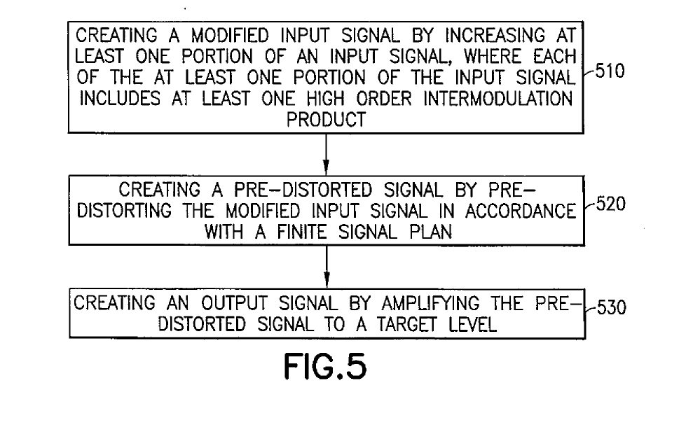

FIG. 5 is a logic flow diagram that illustrates the operation of a method, and a result of execution of computer program instructions, in accordance with exemplary embodiments. In accordance with these exemplary embodiments a method performs, at Block 510, creating a modified input signal by increasing at least one portion of an input signal (such as the whole time domain signal for example). Each of the at least one portion of the input signal comprising high order IM products. At Block 520, the method performs creating a pre-distorted signal by pre-distorting the modified input signal in accordance with a finite signal plan. The method also performs, at Block 530, creating an output signal by amplifying the pre-distorted signal to a target level.

The various blocks shown in FIG. 5 may be viewed as method steps, and/or as operations that result from operation of computer program code, and/or as a plurality of coupled logic circuit elements constructed to carry out the associated function(s).

As shown in FIG. 1, using a power amplifier design with excess peak power (such as one with a high power rating for example) may help mediate the IM product issue; however, this does not remove the high order IM product problem entirely. When power limited devices are chosen instead of high power devices, the IM product problem is worse. For example, a product may use a cheaper low power device to save costs. Regardless, the output power target is similar to that for high rated devices

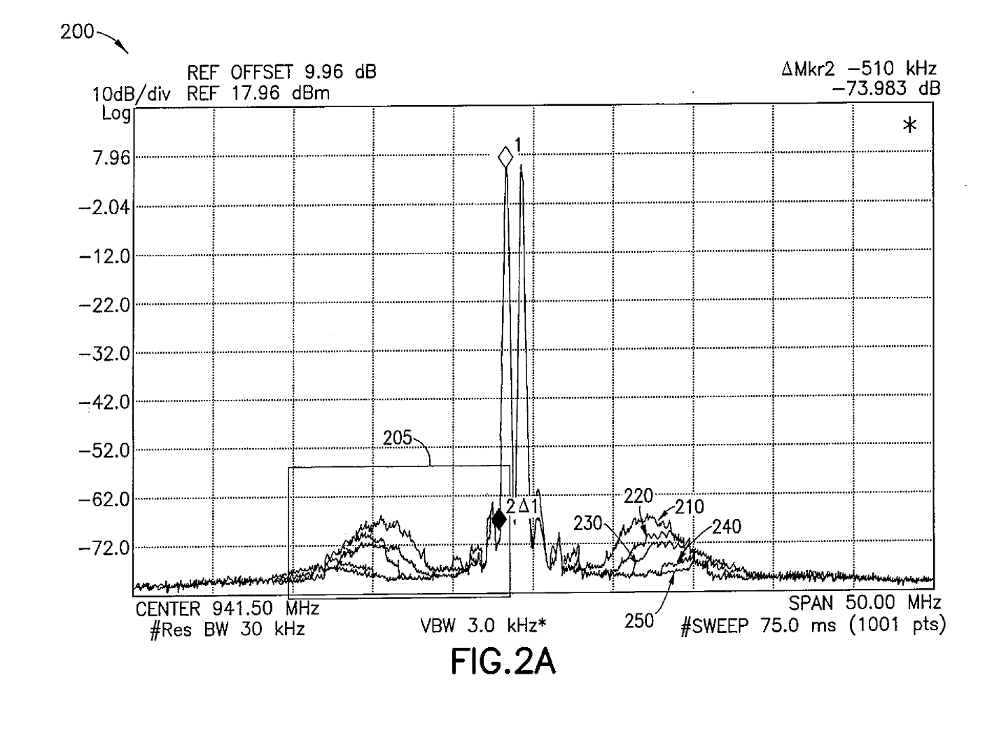

FIG. 2A is a graph 200 which illustrates a high order intermodulation product of a low power rated power amplifier in accordance with various exemplary embodiments. Line 210 shows an uncorrected high order product. In contrast, lines 220-250 show the same high order product which is corrected using increases to the level plan and linearized. Line 220 shows a 1 dB increase, line 230 shows a 2 dB increase, line 240 shows a 3 dB increase and line 250 shows a 3.3 dB increase in the common level plan.

FIG. 2B shows area 205 which is a zoomed-in portion of FIG. 2A. Area 205 is a subsection of graph 200 which is centered on a noise-hump created by a high-order IM product. Line 210 which shows the uncorrected high order product demonstrates more noise than the corrected high order product (lines 220-250). The high order noise hump may experience a correction from −74 dBc (line 210) to −83 dBc (line 250). This is a 9 dB improvement as opposed to 4-5 dB degradation. Thus, a 3.3 dB increase of the input signal results in a factor of 5-10 times improvement in matrix condition. This is sufficient to correct the high order IM products (such as 15th, 17th, etc. for example).

As shown in FIGS. 2A-2B, the high order products are not corrected by the DPD algorithm. However, they are within the 1800 MHz transmit band. Without the necessary correction, the IM products are not satisfactory (such as by failing the wideband noise specification in order to meet 3GPP compliance for example).

The example shown in FIGS. 2A-2B is a 2 carrier GSM case where the high order IM products are in-band. Note that the high order IM product problem is not limited to the GSM waveform. The level plan may be applied to correct cases where the high order IM products are within the radio band (where no suppression from a channel filter/cavity filter may be used). Other waveform products that produce high order IM products outside the radio band may use the standard level plan.

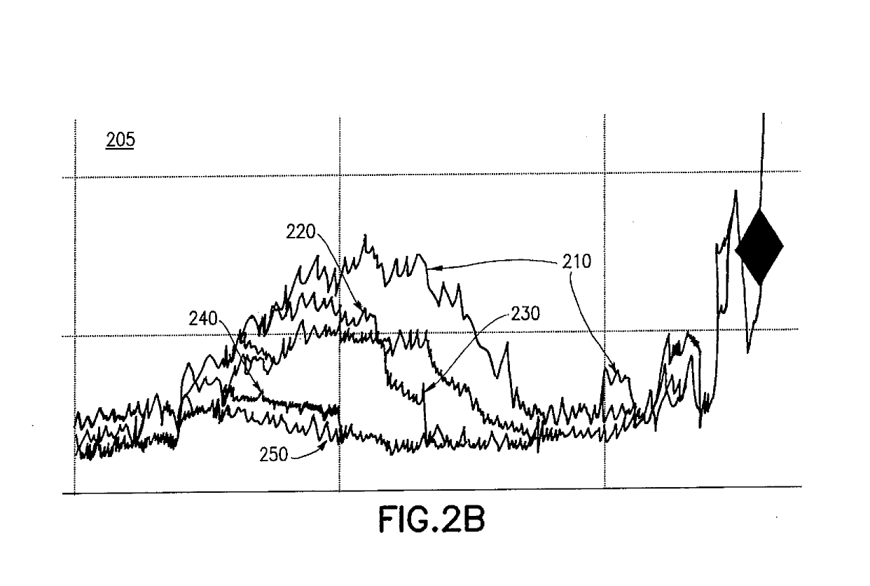

FIG. 3 illustrates a simplified block diagram of various electronic devices and apparatus that are suitable for use in practicing exemplary embodiments.

In FIG. 3, a mobile communication device which may be referred to as a UE 310, is adapted for wireless communication. The UE 310 includes a controller, such as a computer or a DP 314, a computer-readable memory medium embodied as a memory (MEM) 316 that stores a program of computer instructions (PROG) 318, and a suitable wireless interface, such as radio frequency (RF) transceiver 312, for bidirectional wireless communications. The UE 310 also includes a power amplifier (PA) 320 which is configured to provide a signal of appropriate amplitude/power for transmission by the RF transceiver 312.

The PROG 318 is assumed to include program instructions that, when executed by the associated DP, enables the device to operate in accordance with exemplary embodiments, as will be discussed below in greater detail.

That is, various exemplary embodiments may be implemented at least in part by computer software executable by the DP 314 of the UE 310, or by hardware, or by a combination of software and hardware (and firmware).

The UE 310 may also include dedicated processors, for example, digital signal processor (DSP) 315. In the non-limiting embodiment shown, the DSP 315 is shown adjacent to the DP 314; however, in other embodiments, the DSP 315 may be embodied separately or embodied within another component of the UE 310, such as the PA 320 for example.

In general, the various embodiments of the UE 310 can include, but are not limited to, cellular telephones, tablets having wireless communication capabilities, personal digital assistants (PDAs) having wireless communication capabilities, portable computers having wireless communication capabilities, image capture devices such as digital cameras having wireless communication capabilities, gaming devices having wireless communication capabilities, music storage and playback appliances having wireless communication capabilities, Internet appliances permitting wireless Internet access and browsing, as well as portable units or terminals that incorporate combinations of such functions.

The computer readable MEM 316 may be of any type suitable to the local technical environment and may be implemented using any suitable data storage technology, such as semiconductor based memory devices, flash memory, magnetic memory devices and systems, optical memory devices and systems, fixed memory and removable memory. The DP 314 may be of any type suitable to the local technical environment, and may include one or more of general purpose computers, special purpose computers, microprocessors, digital signal processors (DSPs) and processors based on a multicore processor architecture, as non-limiting examples. The wireless interfaces (e.g., RF transceivers 312) may be of any type suitable to the local technical environment and may be implemented using any suitable communication technology such as individual transmitters, receivers, transceivers or a combination of such components.

A DPD signal block may be implemented in either a digital signal processor (DSP), a field-programmable gate array (FPGA) or an application-specific integrated circuit (ASIC). These devices have finite dynamic ranges. Hence, a finite input signal level plan is designed for the DPD block. The level plan is designed to successful pre-distort the input signal for amplification, in various signal formats, such as single carrier GSM (1C-GSM), two carrier-GSM, N-carrier-GSM, N-carrier 8-PSK, N-Carrier-QAM, N-carrier WCDMA, N-Carrier LTE and any combination of all of the above for example. With a power limited PA design, the waveforms are sufficient when a limited number of IM products are observed.

A finite level plan is a plan which relates a limited range of input signal values (such as those in a finite dynamic range for example) to pre-distorted values. According to the finite level plan, an input signal value within the range of input signal values may be correlated to a pre-distorted value. As non-limiting examples, this may be a look-up table based on the input signal value or a calculation optimized for the range of input signal values.

High order IM product issues are related to auto-correlation matrix stability. Auto-correlation is widely used in signal processing to solve least square problems. When higher order IM products are not getting corrected it is an indication that the auto-correlation matrix is not appropriately conditioned. While the same matrix condition is sufficient for correcting low order IM products, the matrix condition may not be sufficient for high order IM correlation.

There are traditional techniques to improve the matrix condition. One such technique is the Tikhonov noise stabilization. This technique adds random noise (small quantity) to the auto-correlation matrix. In normal cases such random noise improves the auto-correlation matrix condition.

DSP, FPGA or ASIC DPD signal blocks have a finite dynamic range when using lookup tables (in some cases with linear interpolation) for high order approximation. The bottom limit of such lookup tables act as a hindrance to matrix condition improvement. This acts as a large noise source at the high order IM products even though this noise will not impact low order IM products. Thus, the auto-correlation matrix condition is not sufficient for the high order IM correction.

An increase of the input signal provided to the DPD does not result in an improvement of auto-correlation matrix condition. Such a signal increase may cause a scalar change to the matrix norm A (∥A∥). The matrix condition is defined as (∥A∥*∥A⁻¹∥). Mathematically, the scalar change will produce the same matrix condition number. Hence, traditional techniques and tools do not provide a solution to the high order IM product problem.

Conventional techniques to avoid the high order IM product problem used high rated power amplifier devices. However, with cost pressures being severe, cheaper low power rated. devices are more desirable for profitability. Accordingly, various exemplary embodiments provide the option to choose cheaper power limited power amplifier devices while not changing the PA output power. By using various exemplary embodiments, such power limited power amplifier devices may correct very high order IM products without changing hardware designs (such as the designs for FPGA, ASIC etc. for example). Additionally, various exemplary embodiments (such as those using a software approach) enable sufficient flexibility to support multiple carrier configurations.

An exemplary embodiment provides a method for correcting high order IM products. The method includes creating (such as by a processor for example) a modified input signal by increasing one or more portions of an input signal (such as the whole time domain signal for example). The input signal consists of a desired signal and other non-linear products. Each of the one or more portions includes high order IM products. A pre-distorted signal is created (such as by a processor for example) by pre-distorting the modified input signal in accordance with a finite signal plan. The method also includes creating (such as by an amplifier for example) an output signal by amplifying the pre-distorted signal to a target level.

In a further exemplary embodiment of the method above, the method also includes transmitting the output signal.

In another exemplary embodiment of any one of the methods above, the method also includes filtering the output signal using a band-pass filter.

In a further exemplary embodiment of any one of the methods above, amplifying the pre-distorted signal is performed using a peak-power limited amplifier.

In another exemplary embodiment of any one of the methods above, creating the pre-distorted signal includes using an auto-correlation matrix to provide parameters for pre-distorting the modified input signal. The method may also include adding random noise to the auto-correlation matrix.

In a further exemplary embodiment of any one of the methods above, a high order IM product is an IM product of at least 13th order.

In another exemplary embodiment of any one of the methods above, increasing the at least one portion includes increasing the at least one portion by 3.3 dB.

In a further exemplary embodiment of any one of the methods above, the input signal is associated with a transmission on a frequency band. Each of the at least one portion also corresponds to a part of the input signal that includes a high order IM product that falls within the frequency band.

In another exemplary embodiment of any one of the methods above, the finite signal plan is configured so that the output signal generated by the pre-distorted signal is relatively linear.

Another exemplary embodiment provides an apparatus for correcting high order IM products. The apparatus includes at least one processor (such as DP 314, DP 315, DP 322, etc. for example); and at least one memory (such as MEM 316 for example) storing computer program code (such as PROG 318 for example). The at least one memory and the computer program code are configured to, with the at least one processor, cause the apparatus to perform actions. The actions include to create a modified input signal by increasing one or more portions of an input signal (such as the whole time domain signal for example). The input signal consists of a desired signal and other non-linear products. Each of the one or more portions includes high order IM products. A pre-distorted signal is created by pre-distorting the modified input signal in accordance with a finite signal plan. The actions also include to create an output signal by amplifying the pre-distorted signal to a target level.

In a further exemplary embodiment of the apparatus above, the actions also include to transmit the output signal.

In another exemplary embodiment of any one of the apparatus above, the actions also include to filter the output signal using a band-pass filter.

In a further exemplary embodiment of any one of the apparatus above, amplifying the pre-distorted signal is performed using a peak-power limited amplifier.

In another exemplary embodiment of any one of the apparatus above, creating the pre-distorted signal includes using an auto-correlation matrix to provide parameters for pre-distorting the modified input signal. The actions may also include to add random noise to the auto-correlation matrix.

In a further exemplary embodiment of any one of the apparatus above, a high order IM product is an IM product of at least 13th order.

In another exemplary embodiment of any one of the apparatus above, increasing the at least one portion includes increasing the at least one portion by 3.3 dB.

In a further exemplary embodiment of any one of the apparatus above, the input signal is associated with a transmission on a frequency band. Each of the at least one portion also corresponds to a part of the input signal that includes a high order IM product that falls within the frequency band.

In another exemplary embodiment of any one of the apparatus above, the finite signal plan is configured so that the output signal generated by the pre-distorted signal is relatively linear.

In a further exemplary embodiment of any one of the apparatus above, the apparatus is embodied in an integrated circuit.

In another exemplary embodiment of any one of the apparatus above, the apparatus is embodied in a mobile device.

Another exemplary embodiment provides a computer readable medium for correcting high order IM products. The computer readable medium (such as MEM 316 for example) is tangibly encoded with a computer program (such as PROG 318) executable by a processor (such as DP 314, DP 315, DP 322, etc. for example) to perform actions. The actions include creating a modified input signal by increasing one or more portions of an input signal (such as the whole time domain signal for example). The input signal consists of a desired signal and other non-linear products. Each of the one or more portions includes high order IM products. A pre-distorted signal is created by pre-distorting the modified input signal in accordance with a finite signal plan. The actions also include creating an output signal by amplifying the pre-distorted signal to a target level.

In a further exemplary embodiment of the computer readable medium above, the actions also include transmitting the output signal.

In another exemplary embodiment of any one of the computer readable medium above, the actions also include filtering the output signal using a band-pass filter.

In a further exemplary embodiment of any one of the computer readable medium above, amplifying the pre-distorted signal is performed using a peak-power limited amplifier.

In another exemplary embodiment of any one of the computer readable medium above, creating the pre-distorted signal includes using an auto-correlation matrix to provide parameters for pre-distorting the modified input signal. The actions may also include adding random noise to the auto-correlation matrix.

In a further exemplary embodiment of any one of the computer readable medium above, a high order IM product is an IM product of at least 13th order.

In another exemplary embodiment of any one of the computer readable medium above, increasing the at least one portion includes increasing the at least one portion by 3.3 dB.

In a further exemplary embodiment of any one of the computer readable medium above, the input signal is associated with a transmission on a frequency band. Each of the at least one portion also corresponds to a part of the input signal that includes a high order IM product that falls within the frequency band.

In another exemplary embodiment of any one of the computer readable medium above, the finite signal plan is configured so that the output signal generated by the pre-distorted signal is relatively linear.

In a further exemplary embodiment of any one of the computer readable media above, the computer readable medium is a storage medium.

In another exemplary embodiment of any one of the computer readable media above, the computer readable medium is a non-transitory computer readable medium (e.g., CD-ROM, RAM, flash memory, etc.).

Another exemplary embodiment provides an apparatus for correcting high order IM products. The apparatus includes means for creating a modified input signal by increasing one or more portions of an input signal (such as the whole time domain signal for example). The input signal consists of a desired signal and other non-linear products. Each of the one or more portions includes high order IM products. The apparatus includes means for creating a pre-distorted signal by pre-distorting the modified input signal in accordance with a finite signal plan. The apparatus also includes means for creating an output signal by amplifying the pre-distorted signal to a target level.

In a further exemplary embodiment of the apparatus above, the apparatus also includes means for transmitting the output signal.

In another exemplary embodiment of any one of the apparatus above, the apparatus also includes means for filtering the output signal using a band-pass filter.

In a further exemplary embodiment of any one of the apparatus above, the output signal creating means is a peak-power limited amplifier.

In another exemplary embodiment of any one of the apparatus above, the pre-distorted signal creating means includes means for using an auto-correlation matrix to provide parameters for pre-distorting the modified input signal. The apparatus may also include means for adding random noise to the auto-correlation matrix.

In a further exemplary embodiment of any one of the apparatus above, a high order IM product is an IM product of at least 13th order.

In another exemplary embodiment of any one of the apparatus above, increasing the at least one portion includes increasing the at least one portion by 3.3 dB.

In a further exemplary embodiment of any one of the apparatus above, the input signal is associated with a transmission on a frequency band. Each of the at least one portion also corresponds to a part of the input signal that includes a high order IM product that falls within the frequency band.

In another exemplary embodiment of any one of the apparatus above, the finite signal plan is configured so that the output signal generated by the pre-distorted signal is relatively linear.

In general, the various exemplary embodiments may be implemented in hardware or special purpose circuits, software, logic or any combination thereof. For example, some aspects may be implemented in hardware, while other aspects may be implemented in firmware or software which may be executed by a controller, microprocessor or other computing device, although not limited thereto. While various aspects of the exemplary embodiments may be illustrated and described as block diagrams, flow charts, or using some other pictorial representation, it is well understood that these blocks, apparatus, systems, techniques or methods described herein may be implemented in, as nonlimiting examples, hardware, software, firmware, special purpose circuits or logic, general purpose hardware or controller or other computing devices, or some combination thereof.

It should thus be appreciated that at least some aspects of the exemplary embodiments may be practiced in various components such as integrated circuit chips and modules, and that the exemplary embodiments may be realized in an apparatus that is embodied as an integrated circuit. The integrated circuit, or circuits, may comprise circuitry (as well as possibly firmware) for embodying at least one or more of a data processor or data processors, a digital signal processor or processors, baseband circuitry and radio frequency circuitry that are configurable so as to operate in accordance with the exemplary embodiments.

Various modifications and adaptations to the foregoing exemplary embodiments may become apparent to those skilled in the relevant arts in view of the foregoing description, when read in conjunction with the accompanying drawings. However, any and all modifications will still fall within the scope of the non-limiting and exemplary embodiments.

It should be noted that the terms “connected,” “coupled,” or any variant thereof, mean any connection or coupling, either direct or indirect, between two or more elements, and may encompass the presence of one or more intermediate elements between two elements that are “connected” or “coupled” together. The coupling or connection between the elements can be physical, logical, or a combination thereof. As employed herein two elements may be considered to be “connected” or “coupled” together by the use of one or more wires, cables and/or printed electrical connections, as well as by the use of electromagnetic energy, such as electromagnetic energy having wavelengths in the radio frequency region, the microwave region and the optical (both visible and invisible) region, as several non-limiting and non-exhaustive examples.

Furthermore, some of the features of the various non-limiting and exemplary embodiments may be used to advantage without the corresponding use of other features. As such, the foregoing description should be considered as merely illustrative of the principles, teachings and exemplary embodiments, and not in limitation thereof.

The following abbreviations that may be found in the specification and/or the drawing figures are defined as follows:

3GPP third generation partnership project

ASIC application-specific integrated circuit

dB decibels

dBc decibels relative to the carrier

DP data processor

DPD digital pre-distortion

DSP digital signal processor

FPGA field-programmable gate array

GSM global system for mobile communications

Hz hertz

IM intermodulation

LTE long term evolution of UTRAN (E-UTRAN)

LUT look-up table

MEM memory

PA power amplifier

PDP pre-distortion processor

PSK phase-shift keying

QAM quadrature amplitude modulation

UE user equipment, such as a mobile station or mobile terminal

UTRAN universal terrestrial radio access network

WCDMA wideband code division multiple access

1. A method comprising:
creating a modified input signal by increasing at least one portion of an input signal, where each of the at least one portion of the input signal comprises at least one high order intermodulation product;
creating a pre-distorted signal by pre-distorting the modified input signal in accordance with a finite signal plan; and
creating an output signal by amplifying the pre-distorted signal.

2. The method of claim 1, further comprising transmitting the output signal.

3. The method of claim 1, further comprising filtering the output signal using a band-pass filter.

4. The method of claim 1, where amplifying the pre-distorted signal is performed using a peak-power limited amplifier.

5. The method of claim 1, where creating the pre-distorted signal comprises using an auto-correlation matrix to provide parameters for pre-distorting the modified input signal.

6. The method of claim 5, further comprising adding random noise to the auto-correlation matrix.

7. The method of claim 1, where the at least one high order intermodulation product comprises an intermodulation product of at least 13th order.

8. The method of claim 1, where the input signal is associated with a transmission on a frequency band and where each of the at least one portion further comprises a high order intermodulation product that falls within the frequency band.

9. The method of claim 1, where the finite signal plan is configured so that the output signal generated by the pre-distorted signal is relatively linear.

10. An apparatus, comprising at least one processor; and at least one memory including computer program code, the at least one memory and the computer program code configured to, with the at least one processor, cause the apparatus to perform at least the following:
to create a modified input signal by increasing at least one portion of an input signal, where each of the at least one portion of the input signal comprises at least one high order intermodulation product;
to create a pre-distorted signal by pre-distorting the modified input signal in accordance with a finite signal plan; and
to create an output signal by amplifying the pre-distorted signal.

11. The apparatus of claim 10, where amplifying the pre-distorted signal is performed using a peak-power limited amplifier.

12. The apparatus of claim 10, where the at least one high order intermodulation product comprises an intermodulation product of at least 13th order.

13. The apparatus of claim 10, where the input signal is associated with a transmission on a frequency band and where each of the at least one portion further comprises a high order intermodulation product that falls within the frequency band.

14. A computer readable medium tangibly encoded with a computer program executable by a processor to perform actions comprising:
creating a modified input signal by increasing at least one portion of an input signal, where each of the at least one portion of the input signal comprises at least one high order intermodulation product;
creating a pre-distorted signal by pre-distorting the modified input signal in accordance with a finite signal plan; and
creating an output signal by amplifying the pre-distorted signal.

15. The computer readable medium of claim 14, where amplifying the pre-distorted signal is performed using a peak-power limited amplifier.

16. The computer readable medium of claim 14, where the at least one high order intermodulation product comprises an intermodulation product of at least 13th order.

17. The computer readable medium of claim 14, where the input signal is associated with a transmission on a frequency band and where each of the at least one portion further comprises a high order intermodulation product that falls within the frequency band.

18. An apparatus comprising:
increasing means for creating a modified input signal by increasing at least one portion of an input signal, where each of the at least one portion of the input signal comprises at least one high order intermodulation product;
pre-distorting means for creating a pre-distorted signal by pre-distorting the modified input signal in accordance with a finite signal plan; and
amplifying means for creating an output signal by amplifying the pre-distorted signal.

19. The apparatus of claim 18, where the amplifying means is a peak-power limited amplifier.

20. The apparatus of claim 18, where the at least one high order intermodulation product comprises an intermodulation product of at least 13th order.

21. The apparatus of claim 18, where the input signal is associated with a transmission on a frequency band and where each of the at least one portion further comprises a high order intermodulation product that falls within the frequency band.
